(19) United States
(12) Patent Application Publication
(10) Pub. No.: US 2025/0219356 A1
(43) Pub. Date: Jul. 3, 2025

(54) VERTICAL-CAVITY SURFACE-EMITTING LASER

(71) Applicant: SONY SEMICONDUCTOR SOLUTIONS CORPORATION, KANAGAWA (JP)

(72) Inventors: RYOMA HIGASHI, KANAGAWA (JP); OSAMU MAEDA, KANAGAWA (JP); KOTA TOKUDA, KANAGAWA (JP); MITSUNARI HOSHI, KANAGAWA (JP); BIPIN SUBEDI, KUMAMOTO (JP)

(21) Appl. No.: 18/843,997

(22) PCT Filed: Jan. 20, 2023
(86) PCT No.: PCT/JP2023/001670

§ 371 Date: Sep. 4, 2024

(30) Foreign Application Priority Data
Mar. 11, 2022 (JP) 2022-037733

(51) Int. Cl. H01S 5/183

(52) U.S. Cl. CPC H01S 5/18377

(57) ABSTRACT

A main object of the present technique is to provide a vertical-cavity surface-emitting laser capable of improving optical output without increasing the operating voltage. The present technique provides a vertical-cavity surface-emitting laser including a first multilayer reflector, an active layer, and a second multilayer reflector, in that order. The first multilayer reflector and/or the second multilayer reflector has a layered structure in which N layered units are layered (where N is a positive integer). The layered unit includes a low refractive index layer, a first graded layer, a high refractive index layer, and a second graded layer, in that order from the active layer side. Average impurity concentrations in the low refractive index layer, the first graded layer, the high refractive index layer, and the second graded layer are in a specific relationship.

### TECHNICAL FIELD

The present technique relates to a vertical-cavity surface-emitting laser.

### BACKGROUND ART

Semiconductor lasers have advantages such as small sizes and long lifespans, and are therefore being used in a variety of applications. Of these, vertical-cavity surface-emitting lasers (VCSELs) have the advantages of being ultra-small and capable of high-speed operation, and are therefore actively being applied in optical communication and light sources for range sensors.

A typical VCSEL includes a Distributed Bragg Reflector (DBR) layer on the substrate. To obtain a high optical output without increasing the operating voltage in a VCSEL, it is desirable to resolve the tradeoff between low resistance and low optical loss in the DBR. Various techniques have been proposed to resolve this tradeoff (e.g., PTL 1 to 3 below).

### CITATION LIST

### Patent Literature

### PTL 1

JP H5-343814A

### PTL 2

JP 2001-332812A

### PTL 3

JP 2005-251860A

### SUMMARY

### Technical Problem

However, there is a need for a vertical-cavity surface-emitting laser capable of achieving even lower resistance and lower optical loss, and improving the optical output without increasing the operating voltage.

Accordingly, a main object of the present technique is to provide a vertical-cavity surface-emitting laser capable of improving optical output without increasing the operating voltage.

### Solution to Problem

That is, the present technique provides a vertical-cavity surface-emitting laser including:

a first multilayer reflector, an active layer, and a second multilayer reflector, in that order,
wherein the first multilayer reflector and/or the second multilayer reflector has a layered structure in which N layered units are layered (where N is a positive integer),
the layered unit includes a low refractive index layer, a first graded layer, a high refractive index layer, and a second graded layer, in that order from a side on which the active layer is located,
the low refractive index layer has a refractive index that is lowest among the layers included in the layered unit,
the high refractive index layer has a refractive index that is highest among the layers included in the layered unit,
a refractive index of the first graded layer increases with distance from the low refractive index layer adjacent thereto in the layering direction,
a refractive index of the second graded layer decreases with distance from the high refractive index layer adjacent thereto in the layering direction, and
when average impurity concentrations of the low refractive index layer, the first graded layer, the high refractive index layer, and the second graded layer included in the layered unit that is M-th (where M is an integer satisfying 2≤M≤N) from the side on which the active layer is located are C_{M1}, C_{M2}, C_{M3}, and C_{M4}, respectively, and an average impurity concentration of the first graded layer included in the layered unit M−1-th from the side on which the active layer is located is C_{M2-1}, then C_{M2}≥C_{M1}, C_{M2}≥C_{M3}, C_{M2}≥C_{M4}, and C_{M2}≥C_{M2-1}.

When the average impurity concentration of the second graded layer included in the layered unit M−1-th from the side on which the active layer is located is C_{M4-1}, then C_{M4}≥C_{M4-1} may hold true.

When an average impurity concentration of the low refractive index layer included in the layered unit M−1-th from the side on which the active layer is located is C_{M1-1}, then C_{M1}≥C_{M1-1} may hold true.

When an average impurity concentration of the high refractive index layer included in the layered unit M−1-th from the side on which the active layer is located is C_{M3-1}, then C_{M3}≥C_{M3-1} may hold true.

In the layered structure of the first multilayer reflector and/or the second multilayer reflector, an average impurity concentration may increase exponentially with distance from the active layer in at least one of a plurality of the low refractive index layers, a plurality of the first graded layers, a plurality of the high refractive index layers, or a plurality of the second graded layers.

C_{M2}≥C_{M4}≥C_{M1} and C_{M2}≥C_{M4}≥C_{M3} may hold true.

When the layered structure is a layered structure in which unit layers each having a thickness t [nm] are layered,
when, in the unit layer K-th (where K is a positive integer) from the side on which the active layer is located, a standing wave intensity is represented by V_{K}, a free carrier absorption is represented by ax [1/cm], a resistance is represented by R_{K} [ohm], and an average impurity concentration is represented by C_{K} [cm⁻³], a function for a distance from a reference point is f(z), and a, b, and c are constants, aₖ and Rₖ may be values represented by the following formula (I) and formula (II), respectively:

$${α}_{K} = 1 - exp ( - a * {C}_{K} * {t}_{K} ) ; and \qquad ( I )$$

$${R}_{K} = b * ( {C}_{K} \hat{} c ) * t * f ( z ) , \qquad ( II )$$

when optical absorption loss in the layered structure is represented by ΣV_{K}·α_{K} and a resistance in the layered structure is represented by ΣR_{K}, and C_{K} is set such that ΣV_{K}·α_{K} is a minimum value and ΣR_{K} is a constant,
a profile of C_{K} and an inverse profile of V_{K} may overlap at least partially. The first multilayer reflector or the second multilayer reflector may be a p-type semiconductor multilayer reflector containing a p-type impurity, and
a concentration of the p-type impurity in the p-type semiconductor multilayer reflector may be at least 7×10¹⁷ cm⁻³ and at most 8×10¹⁸ cm⁻³.

The p-type impurity may include C and/or Zn.

The first multilayer reflector or the second multilayer reflector may be an n-type semiconductor multilayer reflector containing an n-type impurity, and a concentration of the n-type impurity in the n-type semiconductor multilayer reflector may be at least 5×10¹⁷ cm⁻³ and at most 4×10¹⁸ cm⁻³.

The n-type impurity may include at least one element selected from Si, Se, and Te. The first multilayer reflector and/or the second multilayer reflector may be constituted by AlₓGa₁₋ₓAs (0≤x≤1).

The low refractive index layer may be an AlₓGa₁₋ₓ₁As layer (0<x1≤1),
the high refractive index layer may be an Alₓ₂Ga₁₋ₓ₂As layer (0<x2≤x1),
the first graded layer may be an Al_{y1}Ga_{1-y1}As layer (x2≤y1≤x1), and y1 may decrease from x1 to x2 with distance from the low refractive index layer adjacent thereto in the layering direction, and
the second graded layer may be an Al_{y2}Ga_{1-y2}As layer (x2≤y2≤x1), and y2 may increase from x2 to x1 with distance from the high refractive index layer adjacent thereto in the layering direction.

### BRIEF DESCRIPTION OF DRAWINGS

FIG. 1 is a schematic cross-sectional view illustrating an example of a typical configuration of a vertical-cavity surface-emitting laser (VCSEL) according to a past technique.

FIG. 2 is a schematic cross-sectional view illustrating the configuration of a surface-emitting laser according to a first embodiment.

FIG. 3 is a schematic graph illustrating an example of a refractive index, a standing wave intensity, and an average impurity concentration in a multilayer reflector of the surface-emitting laser according to the first embodiment.

FIG. 4 is a schematic graph illustrating an example of an impurity doping concentration and the standing wave intensity in the multilayer reflector of the surface-emitting laser according to the first embodiment.

FIG. 5 is a schematic cross-sectional view illustrating a process for manufacturing the surface-emitting laser according to the first embodiment.

FIG. 6 is a schematic cross-sectional view illustrating a process for manufacturing the surface-emitting laser according to the first embodiment.

FIG. 7 is a schematic cross-sectional view illustrating a process for manufacturing the surface-emitting laser according to the first embodiment.

FIG. 8 is a schematic cross-sectional view illustrating a process for manufacturing the surface-emitting laser according to the first embodiment.

FIG. 9 is a schematic graph illustrating an example of a refractive index, a standing wave intensity, and an average impurity concentration in a multilayer reflector of a surface-emitting laser according to a second embodiment.

FIG. 10 is a schematic graph illustrating an example of a C_{K} profile and a V_{K} inverse profile.

FIG. 11 is a schematic cross-sectional view illustrating the configuration of a surface-emitting laser according to a third embodiment.

FIG. 12 is a schematic graph illustrating an example of a refractive index, a standing wave intensity, and an average impurity concentration in a multilayer reflector of a surface-emitting laser according to a fourth embodiment.

FIG. 13 is a schematic cross-sectional view illustrating the configuration of a surface-emitting laser according to a fifth embodiment.

### DESCRIPTION OF EMBODIMENTS

Suitable embodiments for implementing the present technique will be described hereinafter. The embodiments described hereinafter are typical embodiments of the present technique, and the scope of the present technique is not intended to be limited to these embodiments.

The descriptions will be given in the following order.
1. Vertical-Cavity Surface-Emitting Laser According to Past Technique
2. Vertical-Cavity Surface-Emitting Laser According to Present Technique
2-1. First Embodiment
2-2. Second Embodiment
2-3. Third Embodiment
2-4. Fourth Embodiment
2-5. Fifth Embodiment
2-6. Variations

### 1. Vertical-Cavity Surface-Emitting Laser According to Past Technique

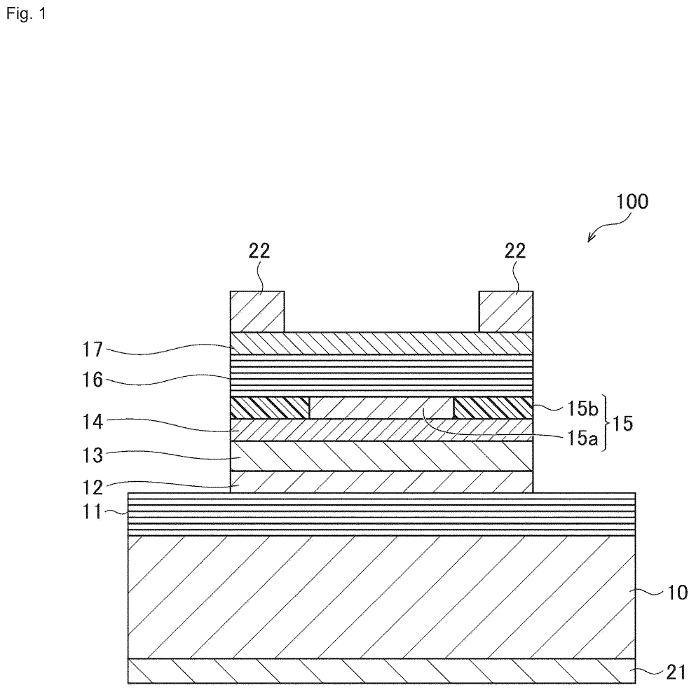

FIG. 1 is a schematic cross-sectional view illustrating an example of a typical configuration of a vertical-cavity surface-emitting laser (VCSEL) 100 according to a past technique. In the VCSEL 100 illustrated in FIG. 1, the upper side is the front side and the lower side is the rear side.

The VCSEL 100 includes a first DBR layer 11, a first spacer layer 12, an active layer 13, a second spacer layer 14, an oxidized layer 15, a second DBR layer 16, and a first contact layer 17 on a substrate 10, in that order. The VCSEL 100 is provided with an electrode 21 on the rear surface and an electrode 22 on the front surface. The first spacer layer 12 to the first contact layer 17 are processed to have a mesa structure. The first DBR layer 11 and the second DBR layer 16 are formed by forming a heterojunction between a pair constituted by a high refractive index layer and a low refractive index layer, which are formed from semiconductor materials, and then layering a plurality of those pairs. The reflectance increases, and the oscillation threshold therefore decreases, as the number of pairs increases.

In a typical VCSEL, there is a problem in that the electrical resistance in the film thickness direction is high due to the large number of pairs of DBRs and the resulting repeated heterojunctions. As such, an insufficient impurity doping concentration will result in a higher operating voltage. To prevent this, it is necessary to reduce the resistance of the DBR by increasing the impurity doping concentration of each layer in the DBR to some extent. However, doing so also increases the loss due to carrier light absorption, which leads to a drop in the optical output. In other words, to obtain a high optical output without increasing the operating voltage, it is necessary to resolve the tradeoff between low resistance and low optical loss in the DBR.

### 2. Vertical-Cavity Surface-Emitting Laser According to Present Technique

A main object of the present technique is to further improve on the past technique described above. In other words, the present technique provides a vertical-cavity surface-emitting laser (also called simply a “surface-emitting laser” hereinafter) capable of achieving even lower resistance and lower optical loss, and improving the optical output without increasing the operating voltage.

### 2-1. First Embodiment

### 2-1-1. Configuration

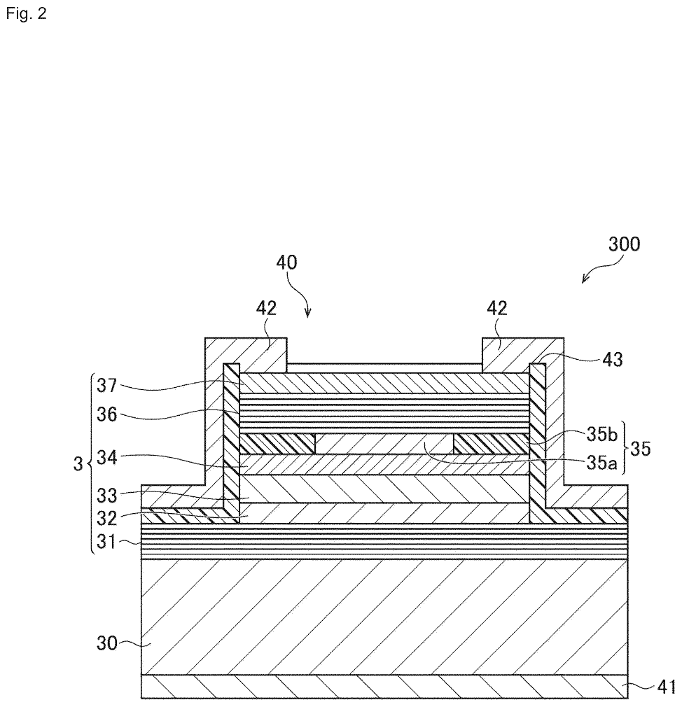

The configuration of the surface-emitting laser according to a first embodiment of the present technique will be described first. FIG. 2 is a schematic cross-sectional view illustrating the configuration of a surface-emitting laser 300 according to the first embodiment. In the surface-emitting laser 300 illustrated in FIG. 2, the upper side is the front side and the lower side is the rear side.

A case where the surface-emitting laser 300 according to the present embodiment is an arsenide semiconductor laser will be described as an example. As used in the present specification, “arsenide semiconductor” refers to a compound semiconductor containing arsenic (As) and at least one element selected from aluminum (Al), gallium (Ga), and indium (In).

As illustrated in FIG. 2, the surface-emitting laser 300 includes a substrate 30 and a semiconductor layered body 3 on the substrate 30. The substrate 30 is, for example, an n-type GaAs substrate. The semiconductor layered body 3 is, for example, a layered body formed from a GaAs-based semiconductor.

The semiconductor layered body 3 includes a first multilayer reflector 31, a first spacer layer 32, an active layer 33, a second spacer layer 34, a current confinement layer 35, a second multilayer reflector 36, and a contact layer 37 in that order from the substrate 30 side. The semiconductor layered body 3 has a cylindrical mesa part 40 protruding in the vertical direction from the substrate 30 in areas aside from part of the first multilayer reflector 31.

The first multilayer reflector 31 is formed on the substrate 30. The multilayer reflector is also called a Distributed Bragg Reflector (DBR). In the present specification, the first multilayer reflector may be a first conductivity type semiconductor multilayer reflector. In the first embodiment, the first conductivity type may be the n type. The first multilayer reflector 31 may be an n-type semiconductor multilayer reflector containing an n-type impurity. In this case, the concentration of the n-type impurity in the n-type semiconductor multilayer reflector is preferably at least 5×10¹⁷ cm⁻³ and at most 4×10¹⁸ cm⁻³. The n-type impurity includes, for example, at least one element selected from silicon (Si), selenium (Se), and tellurium (Te). The first multilayer reflector 31 is constituted by, for example, AlₓGa₁₋ₓAs (0≤x≤1).

The first multilayer reflector 31 has a layered structure in which N layered units are layered (here, N is a positive integer). The layered unit includes a low refractive index layer, a first graded layer, a high refractive index layer, and a second graded layer in that order from the active layer 33 side. In other words, the first multilayer reflector 31 is formed by taking these four layers as one pair and layering a plurality of pairs.

In the first multilayer reflector 31, the refractive indices of the low refractive index layer, the first graded layer, the high refractive index layer, and the second graded layer are as follows. The low refractive index layer has the lowest refractive index among the layers included in the layered unit. The high refractive index layer has the highest refractive index among the layers included in the layered unit. The refractive index of the first graded layer increases with distance from the low refractive index layer adjacent thereto in the layering direction. The refractive index of the second graded layer decreases with distance from the high refractive index layer adjacent thereto in the layering direction.

In the present specification, the refractive index of each layer can be determined by the composition of that layer. For example, if the multilayer reflector is constituted by AlₓGa₁₋ₓAs (0≤x≤1), the magnitude of the refractive index of each layer in the multilayer reflector is determined by the magnitude of the Al ratio in that layer. Specifically, a higher Al ratio results in a lower refractive index. In the present specification, the composition of each layer is obtained through elemental analysis using secondary ion mass spectrometry (SIMS).

In the first multilayer reflector 31, the low refractive index layer may be a first conductivity type (e.g., n-type) Alₓ₁Ga₁₋ₓ₁As layer (0<x1≤1). The high refractive index layer may be a first conductivity type (e.g., n-type) Alₓ₂Ga₁₋ₓ₂As layer (0≤x2<x1). The first graded layer may be a first conductivity type (e.g., n-type) Al_{y1}Ga_{1-y1}As layer (x2≤y1≤x1), where y1 may decrease from x1 to x2 with distance from the low refractive index layer adjacent thereto in the layering direction. The second graded layer may be a first conductivity type (e.g., n-type) Al_{y2}Ga_{1-y2}As layer (x2≤y2≤x1), where y2 may increase from x2 to x1 with distance from the high refractive index layer adjacent thereto in the layering direction.

The first spacer layer 32 is formed between the first multilayer reflector 31 and the active layer 33. In the present specification, the first spacer layer may be a first conductivity type first spacer layer. In the first embodiment, the first spacer layer 32 may be an n-type first spacer layer containing an n-type impurity. The n-type impurity includes, for example, at least one element selected from silicon (Si), selenium (Se), and tellurium (Te). The first spacer layer 32 may be a first conductivity type (e.g., n-type) Alₓ₃Ga₁₋ₓ₃As layer (0≤x3<1).

The active layer 33 is formed between the first spacer layer 32 and the second spacer layer 34. The active layer 33 has a multiple quantum well structure in which, for example, a well layer (not shown) and a barrier layer (not shown) are layered in an alternating manner. The well layer may be an undoped Inₓ₄Ga₁₋ₓAs layer (0<x4<1). The barrier layer may be an undoped Inₓ₅Ga₁₋ₓ₅As layer (0<x5<x4).

The second spacer layer 34 is formed between the active layer 33 and the current confinement layer 35. In the present specification, the second spacer layer may be a second conductivity type second spacer layer. In the first embodiment, the second conductivity type may be the p type. In the first embodiment, the second spacer layer 34 may be a p-type second spacer layer containing a p-type impurity. The p-type impurity includes, for example, at least one element selected from carbon (C), zinc (Zn), magnesium (Mg), and beryllium (Be), and preferably includes carbon (C) and/or zinc (Zn). The second spacer layer 34 may be a second conductivity type (e.g., p-type) Alₓ₆Ga₁₋ₓ₆As layer (0≤x6<1).

The second multilayer reflector 36 is formed between the current confinement layer 35 and the contact layer 37. In the present specification, the second multilayer reflector may be a second conductivity type semiconductor multilayer reflector. In the first embodiment, the second conductivity type may be the p type. The second multilayer reflector 36 may be a p-type semiconductor multilayer reflector containing a p-type impurity. In this case, the concentration of the p-type impurity in the p-type semiconductor multilayer reflector is preferably at least 7×10¹⁷ cm⁻³ and at most 8×10¹⁸ cm⁻³. The p-type impurity includes, for example, at least one element selected from carbon (C), zinc (Zn), magnesium (Mg), and beryllium (Be), and preferably includes carbon (C) and/or zinc (Zn). The second multilayer reflector 36 is constituted by, for example, AlₓGa₁₋ₓAs (0≤x≤1).

The second multilayer reflector 36 has a layered structure in which N layered units are layered (here, N is a positive integer). The layered unit includes a low refractive index layer, a first graded layer, a high refractive index layer, and a second graded layer in that order from the active layer 33 side. In other words, the second multilayer reflector 36 is formed by taking these four layers as one pair and layering a plurality of pairs.

In the second multilayer reflector 36, the refractive indices of the low refractive index layer, the first graded layer, the high refractive index layer, and the second graded layer are as follows. The low refractive index layer has the lowest refractive index among the layers included in the layered unit. The high refractive index layer has the highest refractive index among the layers included in the layered unit. The refractive index of the first graded layer increases with distance from the low refractive index layer adjacent thereto in the layering direction. The refractive index of the second graded layer decreases with distance from the high refractive index layer adjacent thereto in the layering direction.

In the second multilayer reflector 36, the low refractive index layer may be a second conductivity type (e.g., p-type) Alₓ₇Ga₁₋ₓ₇As layer (0<x7≤1). The high refractive index layer may be a second conductivity type (e.g., p-type) Alₓ₈Ga₁₋ₓ₈As layer (0≤x8<x7). The first graded layer may be a second conductivity type (e.g., p-type) Al_{y3}Ga_{1-y3}As layer (x8≤y3≤x7), where y3 may decrease from x7 to x8 with distance from the low refractive index layer adjacent thereto in the layering direction. The second graded layer may be a second conductivity type (e.g., p-type) Al_{y4}Ga_{1-y4}As layer (x8≤y4≤x7), where y4 may increase from x8 to x7 with distance from the high refractive index layer adjacent thereto in the layering direction.

The contact layer 37 is formed on the second multilayer reflector 36. The contact layer 37 is a layer for bringing the second multilayer reflector 36 into ohmic contact with a second electrode layer 42 (described later). In the present specification, the contact layer may be a second conductivity type contact layer. In the first embodiment, the contact layer 37 may be a p-type contact layer containing a p-type impurity. The p-type impurity includes, for example, at least one element selected from carbon (C), zinc (Zn), magnesium (Mg), and beryllium (Be), and preferably includes carbon (C) and/or zinc (Zn). The contact layer 37 may be a second conductivity type (e.g., p-type) Alₓ₉Ga₁₋ₓ₉As layer (0≤x9<1).

The current confinement layer 35 is formed between the second spacer layer 34 and the second multilayer reflector 36. The current confinement layer 35 has a current injection region 35a and a current confinement region 35b. The current injection region 35a is circular, for example. The current confinement region 35b is formed in a periphery of the current injection region 35a. The current injection region 35a may be, for example, a p-type Alₓ₁₀Ga₁₋ₓ₁₀As layer (0<x10≤1). The current confinement region 35b includes aluminum oxide (Al₂O₃), for example. The current confinement region 35b is formed, for example, by the Al contained in an oxidized layer 50 (described later) oxidizing from the side surfaces. The current confinement layer 35 therefore has a function of confining current.

The surface-emitting laser 300 further includes a first electrode layer 41 and the second electrode layer 42. The first electrode layer 41 is formed in contact with the rear side of the substrate 30. The second electrode layer 42 is formed along the front surface of the mesa part 40.

The first electrode layer 41 contains an alloy, and is a layered body in which, for example, (i) an alloy of gold (Au) and germanium (Ge) (AuGe), (ii) nickel (Ni), and (iii) gold (Au) are layered in that order from the substrate 30 side. The second electrode layer 42 is a layered body constituted by a non-alloy, and for example, titanium (Ti), platinum (Pt), and gold (Au) are layered in that order from the substrate 30 side.

### 2-1-2. Average Impurity Concentrations in Multilayer Reflectors

The average impurity concentration of each layer in the first multilayer reflector 31 and/or the second multilayer reflector 36 will be described next. In the first embodiment, the average impurity concentrations in the first multilayer reflector 31 and/or the second multilayer reflector 36 can be designed as follows.

The low refractive index layer, the first graded layer, the high refractive index layer, and the second graded layer included in the M-th layered unit from the active layer side (where M is an integer that satisfies 2≤M≤N) are an M1 layer, an M2 layer, an M3 layer, and an M4 layer, respectively. The standing wave intensity in an Mi layer (where i is 1, 2, 3, or 4) is represented by V_{Mi}. The free carrier absorption in the Mi layer is represented by α_{Mi} [1/cm]. The resistance in the Mi layer is represented by R_{Mi} [ohm]. The average impurity concentration in the Mi layer is represented by C_{Mi} [cm⁻³]. The thickness of the Mi layer is represented by t_{Mi} [nm]. A function related to a distance from a reference point is f(z). a, b, and c are constants. Note that in the present specification, “reference point” refers to a position where current begins to spread. At this time, α_{Mi} and R_{Mi} are the values represented by the following formulae, respectively.

$${α}_{Mi} = 1 - exp ( - a * {C}_{Mi} * {t}_{Mi} )$$

$${R}_{Mi} = b * ( {C}_{Mi} \hat{} c ) * {t}_{Mi} * f ( z )$$

In addition, the optical absorption loss in the stated layered structure and the resistance of the stated layered structure are expressed by the following formulae, respectively.

$$Optical absorption loss = \sum V \cdot α = \sum {V}_{M 1} \cdot {α}_{M 1} + \sum {V}_{M 2} \cdot {α}_{M 2} + \sum {V}_{M 3} \cdot {α}_{M 3} + \sum {V}_{M 4} \cdot {α}_{M 4}$$

$$Resistance = \sum R = \sum {R}_{M 1} + \sum {R}_{M 2} + \sum {R}_{M 3} + \sum {R}_{M 4}$$

The values of the optical absorption loss and resistance are minimized using the average impurity concentration of each layer in the layered structure as a variable. For example, with a layered structure in which 10 of the layered units are provided (i.e., a multilayer reflector in which 10 pairs are layered), an optimization calculation is performed taking the average impurity concentration of the 40 layers as a variable, such that the optical absorption loss is minimized and the resistance is constant. The average impurity concentration of each layer is determined in this manner.

Note that in the present specification, the average impurity concentration is obtained through impurity concentration analysis using secondary ion mass spectrometry (SIMS).

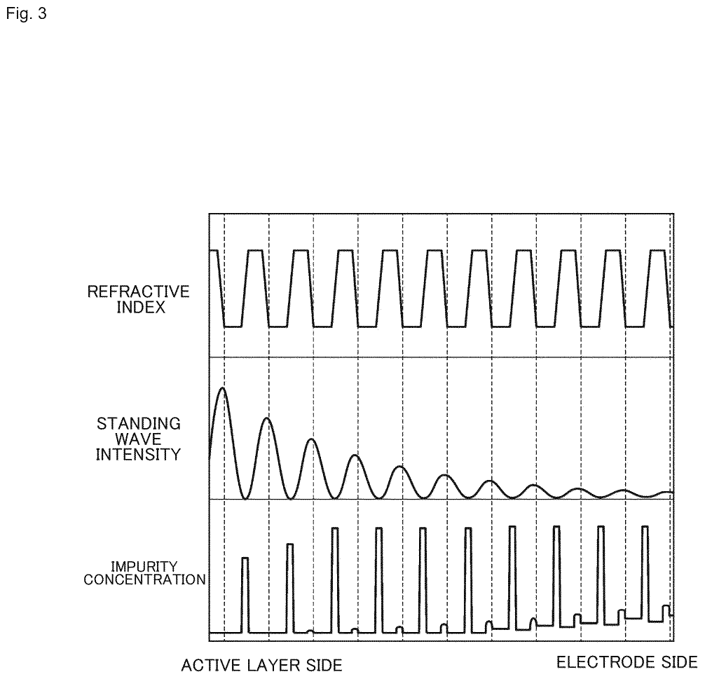

FIG. 3 is a schematic graph illustrating an example of a refractive index, a standing wave intensity, and an average impurity concentration in the multilayer reflector of the surface-emitting laser 300 according to the first embodiment. In the graph, the horizontal axis represents the distance of the surface-emitting laser in a longitudinal direction, and the vertical axis represents the refractive index, the standing wave intensity, and the average impurity concentration (hereinafter simply referred to as “impurity concentration”). The impurity concentration profile illustrated in FIG. 3 is a value determined based on the theory described above.

The first graded layer is located at the node of the standing wave, and the second graded layer is located at the belly of the standing wave. The average impurity concentrations of the low refractive index layer, the first graded layer, the high refractive index layer, and the second graded layer included in the M-th layered unit from the active layer side are represented by C_{M1}, C_{M2}, C_{M3}, and C_{M4}, respectively. The average impurity concentrations of the low refractive index layer, the first graded layer, the high refractive index layer, and the second graded layer included in the M−1-th layered unit from the active layer side are represented by C_{M1-1}, C_{M2-1}, C_{M3-1}, and C_{M1-1}, respectively.

In the surface-emitting laser 300 according to the first embodiment, the magnitude relationship of the impurity concentrations of the layers included in the layered unit is represented as follows. The magnitude relationship of the impurity concentration is derived from the magnitude of the standing wave intensity.

$${C}_{M 2} \geq {C}_{M 1} , {C}_{M 2} \geq {C}_{M 3} , {C}_{M 2} \geq {C}_{M 4} \qquad ( a )$$

Furthermore, the following relationship also holds true for the surface-emitting laser 300 according to the first embodiment.

$${C}_{M 2} \geq {C}_{M 2 - 1} \qquad ( b )$$

In the surface-emitting laser 300 according to the first embodiment, the multilayer reflector has a layered unit designed such that at least (a) and (b) above hold true.

In addition, the following relationship can be established for the impurity concentrations of the layers included in the layered unit.

$${C}_{M 2} \geq {C}_{M 4} \geq {C}_{M 1} \geq {C}_{M 3} \qquad ( c )$$

The relationship in (c) above is considered to be derived by combining the magnitude relationship of the impurity concentrations derived from the magnitude of the standing wave intensity, indicated in the foregoing formula (a), with the magnitude relationship of the impurity concentrations derived from the magnitude of the resistance, indicated in the following formula (d).

$${C}_{M 2} \geq {C}_{M 1} \geq {C}_{M 3} and {C}_{M 4} \geq {C}_{M 1} \geq {C}_{M 3} \qquad ( d )$$

In the first embodiment, it is preferable that the relationship indicated in the following formula (e) be established. Formula (e) can be derived from the foregoing formula (c).

$${C}_{M 2} \geq {C}_{M 4} \geq {C}_{M 1} and {C}_{M 2} \geq {C}_{M 4} \geq {C}_{M 3} \qquad ( e )$$

In the first embodiment, it is preferable that the relationship indicated in the following formula (f) be established.

$${C}_{M 4} \geq {C}_{M 4 - 1} \qquad ( f )$$

In the first embodiment, it is preferable that at least one of the relationships indicated in the following formulae (g) and (h) be established.

$${C}_{M 1} \geq {C}_{M 1 - 1} \qquad ( g )$$

$${C}_{M 3} \geq {C}_{M 3 - 1} \qquad ( h )$$

Because the standing wave intensity increases with proximity to the active layer, optical absorption loss can be suppressed throughout the entire multilayer reflector by making the impurity concentration lower with proximity to the active layer.

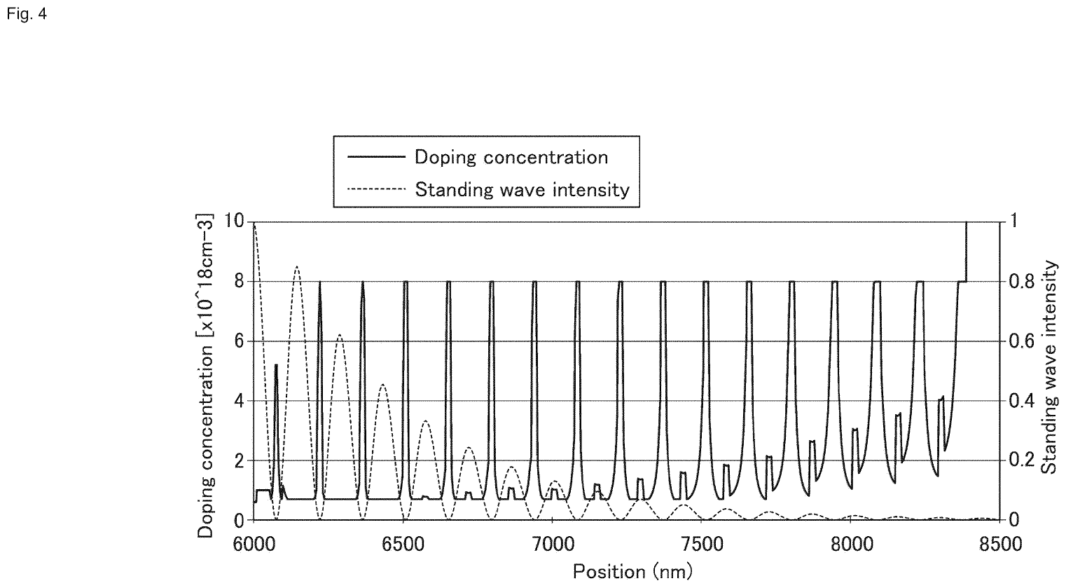

FIG. 4 is a schematic graph illustrating an example of the impurity doping concentration (average impurity concentration) and the standing wave intensity in the multilayer reflector of the surface-emitting laser 300 according to the first embodiment. In this graph, the solid line indicates the impurity doping concentration (average impurity concentration), and the broken line indicates the standing wave intensity. As indicated by the graph, the impurity doping concentration (average impurity concentration) in at least one of the low refractive index layer, the first graded layer, the high refractive index layer, or the second graded layer increases exponentially with distance from the active layer (i.e., as the value on the horizontal axis increases) in at least a part of the multilayer reflector. This corresponds to the fact that the envelope of the standing wave intensity curve decreases exponentially with distance from the active layer.

In this manner, it is preferable that in the layered structure of the first multilayer reflector 31 and/or the second multilayer reflector 36 of the first embodiment, the average impurity concentration increases exponentially with distance from the active layer in at least one of the plurality of low refractive index layers, the plurality of first graded layers, the plurality of high refractive index layers, or the plurality of second graded layers. This makes it possible to increase the average impurity concentration to correspond to the standing wave intensity, which decreases gradually with distance from the active layer. This can contribute to achieving even lower resistance and lower optical loss.

As described above, each layer in the first multilayer reflector 31 and/or the second multilayer reflector 36 has a specific impurity concentration. Therefore, when the first multilayer reflector 31 and/or the second multilayer reflector 36 are viewed as a whole, the impurity concentration is relatively higher in layers having a lower standing wave intensity, whereas the impurity concentration is relatively lower in layers having a higher standing wave intensity. This makes it possible to suppress the resistance of the multilayer reflector as a whole and to minimize optical absorption loss in the multilayer reflector as a whole. In other words, even lower resistance and optical loss can be achieved. This makes it possible to provide a surface-emitting laser capable of improving the optical output without increasing the operating voltage.

In the surface-emitting laser 300 according to the first embodiment, at least one of the first multilayer reflector 31 or the second multilayer reflector 36 may have the specific impurity concentration mentioned above. When one is a p-type semiconductor multilayer reflector and the other is an n-type semiconductor multilayer reflector, it is preferable that the p-type semiconductor multilayer reflector have the specific impurity concentration mentioned above. To achieve even lower resistance and optical loss in the surface-emitting laser 300 as a whole, it is further preferable that both the first multilayer reflector 31 and the second multilayer reflector 36 have the specific impurity concentration mentioned above.

### 2-1-3. Manufacturing Method

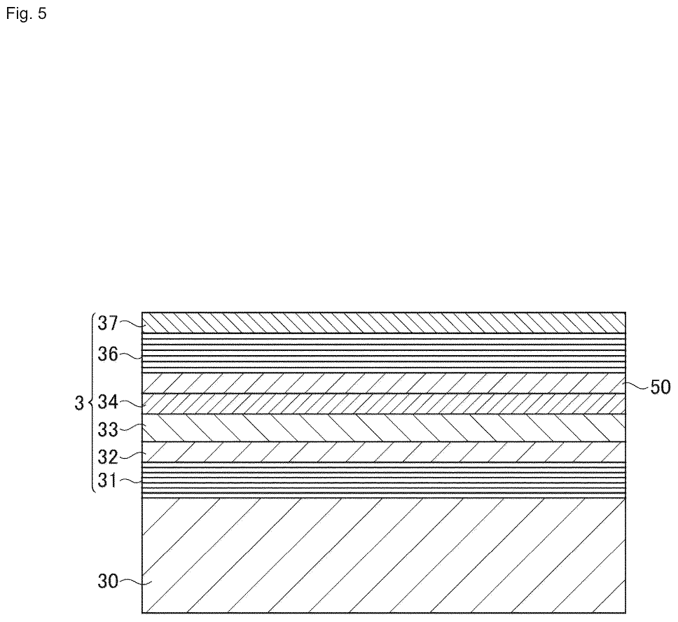

A method for manufacturing the surface-emitting laser 300 according to the first embodiment will be described next. FIGS. 5 to 8 are schematic cross-sectional views illustrating a process for manufacturing the surface-emitting laser 300 according to the first embodiment.

To manufacture the surface-emitting laser 300, a compound semiconductor is formed on the substrate 30, which is constituted by GaAs, for example, at once through an epitaxial crystal growth technique such as Metal Organic Chemical Vapor Deposition (MOCVD), for example. A methyl organic metal gas such as trimethyl aluminum (TMAl), trimethyl gallium (TMGa), trimethyl indium (TMIn), or the like, and arsine (AsH₃) gas, for example, are used as the materials for the compound semiconductor. Disilane (Si₂H₆) is used as the material of the donor impurity, for example. Carbon tetrabromide (CBr₄) is used as the material of the acceptor impurity, for example.

First, as illustrated in FIG. 5, the first multilayer reflector 31, the first spacer layer 32, the active layer 33, the second spacer layer 34, the oxidized layer 50, the second multilayer reflector 36, and the contact layer 37 are formed in that order on the front surface of the substrate 30 through an epitaxial crystal growth technique such as MOCVD, for example.

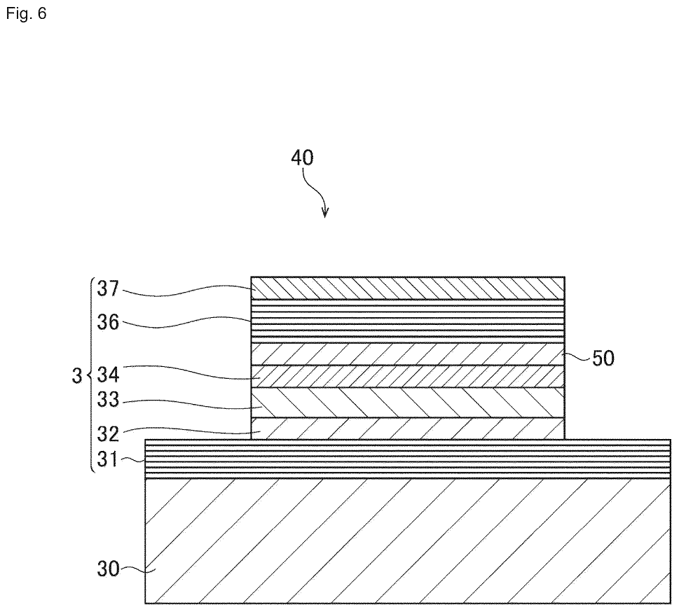

Next, after forming a resist layer (not shown) in a predetermined pattern, the contact layer 37, the second multilayer reflector 36, the oxidized layer 50, the second spacer layer 34, the active layer 33, and the first spacer layer 32 are selectively etched using the resist layer as a mask. As a result, the cylindrical mesa part 40 is formed to a height that reaches the front surface of the first multilayer reflector 31, as illustrated in FIG. 6. As the etching technique, RIE (Reactive Ion Etching) with CL gas is used, for example. The resist layer is then removed.

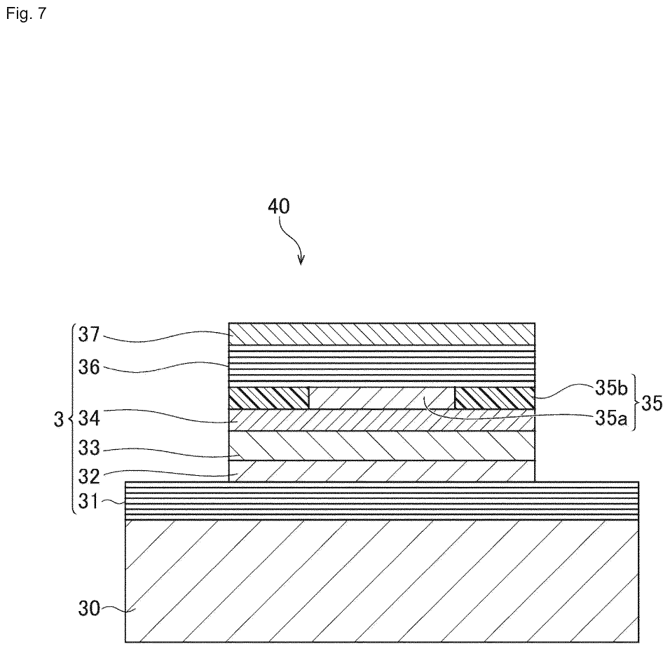

An oxidation process is then performed at a high temperature in a water vapor atmosphere, and the Al contained in the oxidized layer 50 is selectively oxidized from the side surfaces of the mesa part 40. Alternatively, a wet oxidation technique is used to selectively oxidize the Al contained in the oxidized layer 50 from the side surfaces of the mesa part 40. As a result, within the mesa part 40, an outer edge region of the oxidized layer 50 becomes an insulating layer (aluminum oxide), and the current confinement region 35b is formed as a result, as illustrated in FIG. 7.

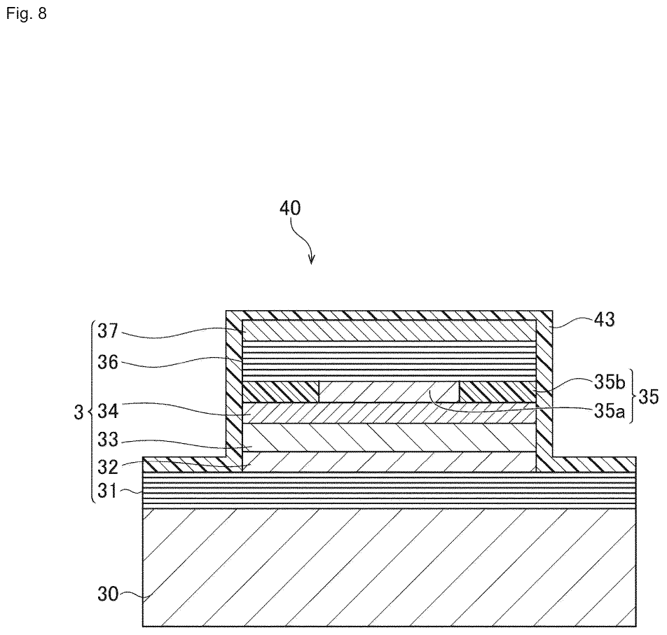

Next, as illustrated in FIG. 8, an insulating layer 43 is formed on the mesa part 40 and on the first multilayer reflector 31 in the periphery of the mesa part 40. The insulating layer 43 is constituted by an insulative resin such as polyimide, for example. The insulating layer 43 is preferably formed using chemical vapor deposition (CVD). This is because the insulating layer 43 prevents components such as the first multilayer reflector 31, the second multilayer reflector 36, and the current confinement layer 35b from being in contact with moisture, and also electrically separates the components from the second electrode layer 42, and it is therefore necessary to improve the film properties on the side surfaces of the mesa part 40. More specifically, plasma CVD or thermal CVD can be used, for example. Spin coating may also be used, for example, to make the insulating layer 43 flat. To improve the film properties, it is preferable to use CVD before and after spin coating.

Next, the insulating layer 43 is selectively removed using dry etching, for example. This partially exposes the contact layer 37. The second electrode layer 42 is then formed by layering Ti, Pt, and Au, for example, in that order, on the mesa part 40 and on the insulating layer 43 in the periphery of the mesa part 40, through vacuum deposition, for example. Then, the thickness of the rear surface of the substrate 10 is adjusted as appropriate through polishing, after which the first electrode layer 41 is formed on the surface thereof by layering AuGe, Ni, and Au, for example, in that order.

Finally, after removing part of the insulating layer 43 subjected to dicing, the substrate 30 is diced. The surface-emitting laser 300 is manufactured through the procedure described above.

### 2-2. Second Embodiment

A surface-emitting laser according to a second embodiment of the present technique will be described next. The second embodiment may have basically the same configuration as the first embodiment, but the impurity concentration profile of the multilayer reflector is different from that in the first embodiment.

### 2-2-1. Configuration

The configuration of the surface-emitting laser according to the second embodiment may be basically the same as in the first embodiment described above. Accordingly, the descriptions of the configuration of the first embodiment also apply to the second embodiment.

### 2-2-2. Average Impurity Concentrations in Multilayer Reflectors

In the second embodiment, the average impurity concentrations in the first multilayer reflector and/or the second multilayer reflector can be designed as follows.

The layered structure of the first multilayer reflector and/or the second multilayer reflector is a layered structure in which unit layers having a thickness t [nm] are layered. In this case, in a K-th unit layer from the active layer side (where K is a positive integer), the standing wave intensity is represented by V_{K}, the free carrier absorption is represented by α_{K} [1/cm], the resistance is represented by R_{K} [ohm], and the average impurity concentration is represented by C_{K} [cm⁻³]. A function related to a distance from a reference point is f(z). a, b, and c are constants. At this time, αₖ and R_{K} are the values represented by the following formulae (I) and (II), respectively.

$${α}_{K} = 1 - exp ( - a * {C}_{K} * {t}_{K} ) \qquad ( I )$$

$${R}_{K} = b * ( {C}_{K} \hat{} c ) * t * f ( z ) \qquad ( II )$$

In addition, the optical absorption loss in the stated layered structure and the resistance of the stated layered structure are expressed by the following formulae, respectively.

$$Optical absorption loss = \sum {V}_{K} \cdot {α}_{K}$$

$$Resistance = \sum {R}_{K}$$

In this case, the values of the optical absorption loss and resistance are minimized using the average impurity concentration of each unit layer as a variable. For example, when the multilayer reflector is 1500 nm thick and the unit layers are 2 nm thick, an optimization calculation is performed taking the average impurity concentration of a layered structure in which 750 unit layers are layered as a variable, such that the optical absorption loss is minimized and the resistance is constant. The average impurity concentration of each unit layer is determined in this manner.

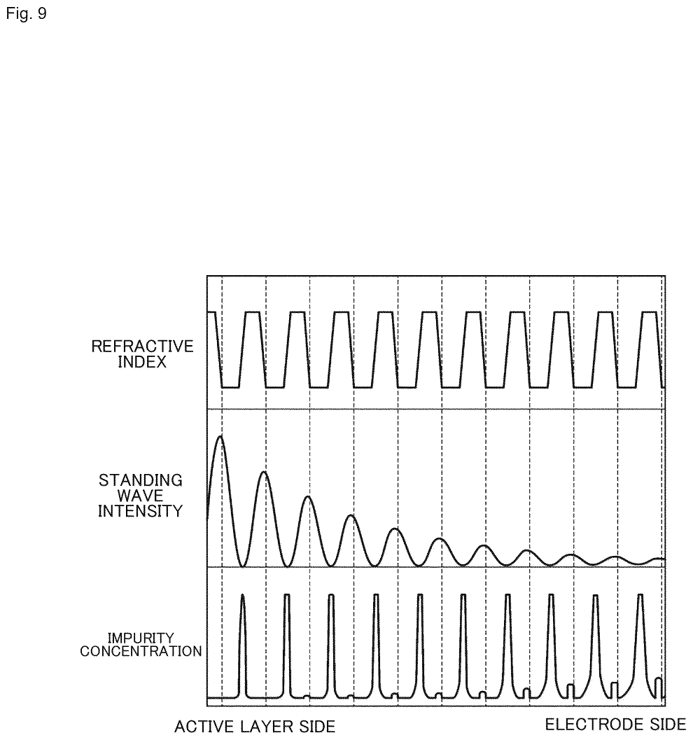

FIG. 9 is a schematic graph illustrating an example of a refractive index, a standing wave intensity, and an average impurity concentration in the multilayer reflector of the surface-emitting laser according to the second embodiment. In the graph, the horizontal axis represents the distance of the surface-emitting laser in a longitudinal direction, and the vertical axis represents the refractive index, the standing wave intensity, and the average impurity concentration. The impurity concentration profile illustrated in FIG. 9 is a value determined based on the theory described above.

The first graded layer is located at the node of the standing wave, and the second graded layer is located at the belly of the standing wave. The average impurity concentrations of the low refractive index layer, the first graded layer, the high refractive index layer, and the second graded layer included in the M-th layered unit from the active layer side are represented by C_{M1}, C_{M2}, C_{M3}, and C_{M4}, respectively. The average impurity concentrations of the low refractive index layer, the first graded layer, the high refractive index layer, and the second graded layer included in the M−1-th layered unit from the active layer side are represented by C_{M1-1}, C_{M2-1}, C_{M3-1}, and C_{M4-1}, respectively.

In the surface-emitting laser according to the second embodiment, the magnitude relationship of the impurity concentrations of the layers included in the layered unit is represented as follows. The magnitude relationship of the impurity concentration is derived from the magnitude of the standing wave intensity.

$${C}_{M 2} \geq {C}_{M 1} , {C}_{M 2} \geq {C}_{M 3} , {C}_{M 2} \geq {C}_{M 4} \qquad ( a )$$

Furthermore, the following relationship also holds true for the surface-emitting laser according to the second embodiment.

$${C}_{M 2} \geq {C}_{M 2 - 1} \qquad ( b )$$

In the surface-emitting laser according to the second embodiment, the multilayer reflector has a layered unit designed such that at least (a) and (b) above hold true.

In addition, the following relationship can be established for the impurity concentrations of the layers included in the layered unit.

$${C}_{M 2} \geq {C}_{M 4} \geq {C}_{M 1} \geq {C}_{M 3} \qquad ( c )$$

The relationship in (c) above is considered to be derived by combining the magnitude relationship of the impurity concentrations derived from the magnitude of the standing wave intensity, indicated in the foregoing formula (a), with the magnitude relationship of the impurity concentrations derived from the magnitude of the resistance, indicated in the following formula (d).

$${C}_{M 2} \geq {C}_{M 1} \geq {C}_{M 3} and {C}_{M 4} \geq {C}_{M 1} \geq {C}_{M 3} \qquad ( d )$$

In the second embodiment, it is preferable that the relationship indicated in the following formula (e) be established. Formula (e) can be derived from the foregoing formula (c).

$${C}_{M 2} \geq {C}_{M 4} \geq {C}_{M 1} and {C}_{M 2} \geq {C}_{M 4} \geq {C}_{M 3} \qquad ( e )$$

In the second embodiment, it is preferable that the relationship indicated in the following formula (f) be established.

$${C}_{M 4} \geq {C}_{M 4 - 1} \qquad ( f )$$

In the second embodiment, it is preferable that at least one of the relationships indicated in the following formulae (g) and (h) be established.

$${C}_{M 1} \geq {C}_{M 1 - 1} \qquad ( g )$$

$${C}_{M 3} \geq {C}_{M 3 - 1} \qquad ( h )$$

Because the standing wave intensity increases with proximity to the active layer, optical absorption loss can be suppressed throughout the entire multilayer reflector by making the impurity concentration lower with proximity to the active layer.

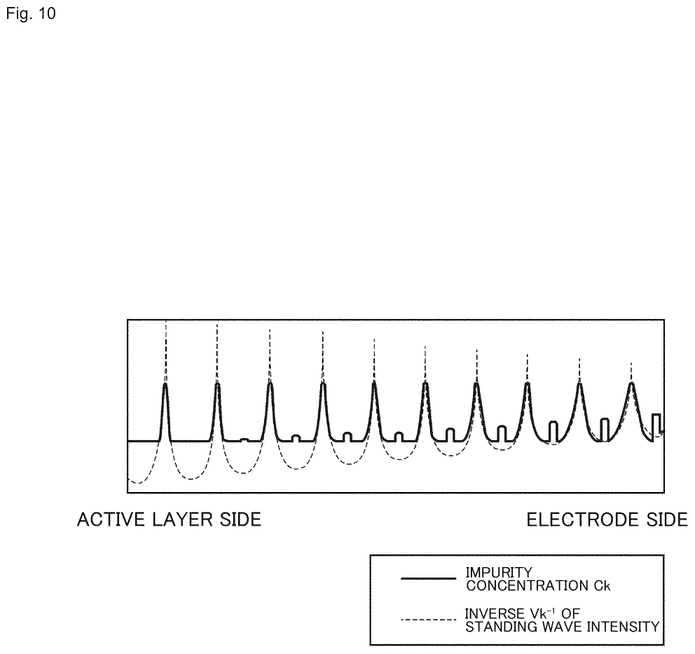

Furthermore, as described above, when the optical absorption loss in the layered structure is ΣV_{K}·α_{K} and the resistance of the layered structure is set to ΣR_{K}, and C_{K} is set such that ΣV_{K} ax is a minimum value and ΣR_{K} is a constant, the C_{K} profile and the V_{K} inverse profile overlap at least partially. FIG. 10 is a schematic graph illustrating an example of the C_{K} profile (impurity concentration profile) and the V_{K} inverse profile (the inverse profile of the standing wave intensity). Ensuring that the C_{K} profile and the V_{K} inverse profile overlap at least partially makes it possible to dope parts having a higher standing wave intensity with a lower concentration of impurities and dope parts having a lower standing wave intensity with a higher concentration of impurities. As a result, the resistance and optical absorption loss of the multilayer reflector as a whole can be minimized.

In the first embodiment described above, the impurity concentration is set for each layer in the multilayer reflector. In contrast, in the second embodiment, the impurity concentration is set for each unit layer, in 2 nm increments, for example.

As such, the second embodiment provides a finer impurity concentration profile than the first embodiment. It is therefore thought that the second embodiment can achieve a further reduction in resistance and optical loss than the first embodiment. As a result, the effect of increasing the optical output without increasing the operating voltage can be anticipated to be achieved even more than in the first embodiment.

In the surface-emitting laser according to the second embodiment, at least one of the first multilayer reflector or the second multilayer reflector may have the specific impurity concentration mentioned above. When one is a p-type semiconductor multilayer reflector and the other is an n-type semiconductor multilayer reflector, it is preferable that the p-type semiconductor multilayer reflector have the specific impurity concentration mentioned above. To achieve even lower resistance and optical loss in the multilayer reflector as a whole, it is further preferable that both the first multilayer reflector and the second multilayer reflector have the specific impurity concentration mentioned above.

### 2-3. Third Embodiment

A surface-emitting laser according to a third embodiment of the present technique will be described next. The third embodiment basically reverses the conductivity types (p-type and n-type) in the surface-emitting laser according to the second embodiment.

### 2-3-1. Configuration

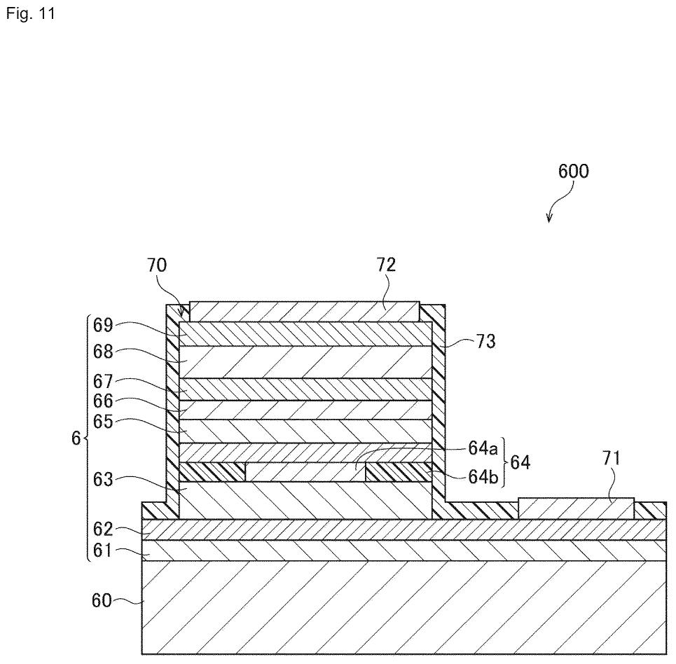

FIG. 11 is a schematic cross-sectional view illustrating the configuration of a surface-emitting laser 600 according to the third embodiment. In the surface-emitting laser 600 illustrated in FIG. 11, the upper side is the front side and the lower side is the rear side.

As illustrated in FIG. 11, the surface-emitting laser 600 includes a substrate 60 and a semiconductor layered body 6 on the substrate 60. The substrate 60 is, for example, a semi-insulative substrate constituted by GaAs. Specifically, a resistivity R_{sub} [ohm] of the substrate 60 is a value that satisfies, for example, 1.0×10⁶ ohm<R_{sub}<1.0×10¹² ohm. The semiconductor layered body 6 is, for example, a layered body formed from a GaAs-based semiconductor.

The semiconductor layered body 6 includes a current diffusion layer 61, a first contact layer 62, a first multilayer reflector 63, a current confinement layer 64, a first spacer layer 65, an active layer 66, a second spacer layer 67, a second multilayer reflector 68, and a second contact layer 69, in that order from the substrate 60 side. The semiconductor layered body 6 has a cylindrical mesa part 70 protruding in the vertical direction from the substrate 60 in areas aside from part of the current diffusion layer 61 and the first contact layer 62.

The current diffusion layer 61 is formed on the substrate 60. The current diffusion layer 61 may be a p-type current diffusion layer containing a p-type impurity. The p-type impurity includes, for example, at least one element selected from carbon (C), zinc (Zn), magnesium (Mg), and beryllium (Be), and preferably includes carbon (C) and/or zinc (Zn). The p-type current diffusion layer may be a p-type Alₓ₋₁₁Ga₁₋ₓ₁₁As layer (0≤x11<1).

The first contact layer 62 is formed between the current diffusion layer 61 and the first multilayer reflector 63. The first contact layer 62 may be a p-type first contact layer containing a p-type impurity. The p-type first contact layer may be a p-type Alₓ₁₂Ga₁₋ₓ₁₂As layer (0≤x12<1).

The first multilayer reflector 63 is formed between the first contact layer 62 and the current confinement layer 64. The first multilayer reflector 63 may be a p-type semiconductor multilayer reflector containing a p-type impurity. In this case, the concentration of the p-type impurity in the p-type semiconductor multilayer reflector is preferably at least 7×10¹⁷ cm⁻³ and at most 8×10¹⁸ cm⁻³. The p-type impurity includes, for example, at least one element selected from carbon (C), zinc (Zn), magnesium (Mg), and beryllium (Be), and preferably includes carbon (C) and/or zinc (Zn).

The first multilayer reflector 63 has a layered structure in which N layered units are layered (here, N is a positive integer). The layered unit includes a low refractive index layer, a first graded layer, a high refractive index layer, and a second graded layer in that order from the active layer 66 side. In other words, the first multilayer reflector 63 is formed by taking these four layers as one pair and layering a plurality of pairs.

In the first multilayer reflector 63, the refractive indices of the low refractive index layer, the first graded layer, the high refractive index layer, and the second graded layer are as follows. The low refractive index layer has the lowest refractive index among the layers included in the layered unit. The high refractive index layer has the highest refractive index among the layers included in the layered unit. The refractive index of the first graded layer increases with distance from the low refractive index layer adjacent thereto in the layering direction. The refractive index of the second graded layer decreases with distance from the high refractive index layer adjacent thereto in the layering direction.

In the first multilayer reflector 63, the low refractive index layer may be a p-type Alₓ₁₃Ga₁₋ₓ₁₃As layer (0<x13≤1). The high refractive index layer may be a p-type Alₓ₁₄Ga₁₋ₓ₁₄As layer (0≤x14<x13). The first graded layer may be a p-type Al_{y5}Ga_{1-y5}As layer (x14≤y5≤x13), where y5 may decrease from x13 to x14 with distance from the low refractive index layer adjacent thereto in the layering direction. The second graded layer may be a p-type Al_{y6}Ga_{1-y6}As layer (x14≤y6≤ x13), where y6 may increase from x14 to x13 with distance from the high refractive index layer adjacent thereto in the layering direction.

The first spacer layer 65 is formed between the current confinement layer 64 and the active layer 66. The first spacer layer 65 may be a p-type first spacer layer containing a p-type impurity. The p-type impurity includes, for example, at least one element selected from carbon (C), zinc (Zn), magnesium (Mg), and beryllium (Be), and preferably includes carbon (C) and/or zinc (Zn). The p-type first spacer layer may be a p-type Alₓ₁₅Ga₁₋ₓ₁₅As layer (0≤x15<1).

The active layer 66 is formed between the first spacer layer 65 and the second spacer layer 67. The active layer 66 has a multiple quantum well structure in which, for example, a well layer (not shown) and a barrier layer (not shown) are layered in an alternating manner. The well layer may be an undoped Inₓ₁₆Ga₁₋ₓ₁₆As layer (0<x16<1). The barrier layer may be, for example, an undoped Inₓ₁₇Ga₁₋ₓ₁₇As layer (0<x17<x16).

The second spacer layer 67 is formed between the active layer 66 and the second multilayer reflector 68. The second spacer layer 67 may be an n-type second spacer layer containing an n-type impurity. The n-type impurity includes, for example, at least one element selected from silicon (Si), selenium (Se), and tellurium (Te). The second spacer layer 67 may be an n-type Alₓ₁₈Ga₁₋ₓ₁₈As layer (0≤x18<1).

The second multilayer reflector 68 is formed between the second spacer layer 67 and the second contact layer 69. The second multilayer reflector 68 may be an n-type semiconductor multilayer reflector containing an n-type impurity. In this case, the concentration of the n-type impurity in the n-type semiconductor multilayer reflector is preferably at least 5×10¹⁷ cm⁻³ and at most 4×10¹⁸ cm⁻³. The n-type impurity includes, for example, at least one element selected from silicon (Si), selenium (Se), and tellurium (Te).

The second multilayer reflector 68 has a layered structure in which N layered units are layered (here, N is a positive integer). The layered unit includes a low refractive index layer, a first graded layer, a high refractive index layer, and a second graded layer in that order from the active layer 66 side. In other words, the second multilayer reflector 68 is formed by taking these four layers as one pair and layering a plurality of pairs.

In the second multilayer reflector 68, the refractive indices of the low refractive index layer, the first graded layer, the high refractive index layer, and the second graded layer are as follows. The low refractive index layer has the lowest refractive index among the layers included in the layered unit. The high refractive index layer has the highest refractive index among the layers included in the layered unit. The refractive index of the first graded layer increases with distance from the low refractive index layer adjacent thereto in the layering direction. The refractive index of the second graded layer decreases with distance from the high refractive index layer adjacent thereto in the layering direction.

In the second multilayer reflector 68, the low refractive index layer may be an n-type Alₓ₁₉Ga₁₋ₓ₁₉As layer (0<x19≤1). The high refractive index layer may be an n-type Alₓ₂₀Ga₁₋ₓ₂₀As layer (0≤x20<x19). The first graded layer may be an n-type Al_{y7}Ga_{1-y7}As layer (x20≤y7≤x19), where y7 may decrease from x19 to x20 with distance from the low refractive index layer adjacent thereto in the layering direction. The second graded layer may be an n-type Al_{y8}Ga_{1-y8}As layer (x20≤y8≤x19), where y8 may increase from x20 to x19 with distance from the high refractive index layer adjacent thereto in the layering direction.

The second contact layer 69 is formed on the second multilayer reflector 68. The second contact layer 69 is a layer for bringing the second multilayer reflector 68 into ohmic contact with a second electrode layer 72 (described later). The second contact layer 69 may be an n-type second contact layer containing an n-type impurity. The n-type impurity includes, for example, at least one element selected from silicon (Si), selenium (Se), and tellurium (Te). The second contact layer 69 may be an n-type Alₓ₂₁Ga₁₋ₓ₂₁As layer (0≤x21<1).

The current confinement layer 64 is formed between the first multilayer reflector 63 and the first spacer layer 65. The current confinement layer 64 has a current injection region 64a and a current confinement region 64b. The current injection region 64a is circular, for example. The current confinement region 64b is formed in a periphery of the current injection region 64a. The current injection region 64a may be a p-type Alₓ₂₂Ga₁₋ₓ₂₂As layer (0<x22≤1). The current confinement region 64b includes aluminum oxide (Al₂O₃), for example. The current confinement region 64b is formed, for example, by the Al contained in an oxidized layer 50 (described later) oxidizing from the side surfaces. The current confinement layer 64 therefore has a function of confining current.

The surface-emitting laser 600 further includes a first electrode layer 71 and the second electrode layer 72. The first electrode layer 71 is formed in contact with the first contact layer 62 in the base of the mesa part 70. The second electrode layer 72 is formed in contact with the second contact layer 69 and along the upper surface of the mesa part 70.

The first electrode layer 71 is a layered body constituted by a non-alloy, and for example, titanium (Ti), platinum (Pt), and gold (Au) are layered in that order from the first contact layer 62 side. The second electrode layer 72 contains an alloy, and is a layered body in which, for example, (i) an alloy of gold (Au) and germanium (Ge) (AuGe), (ii) nickel (Ni), and (iii) gold (Au) are layered in that order from the second contact layer 69 side.

### 2-3-2. Average Impurity Concentrations in Multilayer Reflectors

In the third embodiment, the impurity concentration profiles of the first multilayer reflector and/or the second multilayer reflector may be the same as in the second embodiment. Accordingly, the descriptions pertaining to the average impurity concentrations in the multilayer reflector given in the second embodiment also apply to the third embodiment.

In the surface-emitting laser according to the third embodiment, when the first multilayer reflector and/or the second multilayer reflector are viewed as a whole, the impurity concentration is relatively higher in parts having a lower standing wave intensity, whereas the impurity concentration is relatively lower in parts having a higher standing wave intensity. This makes it possible to suppress the resistance of the multilayer reflector as a whole and to minimize optical absorption loss in the multilayer reflector as a whole. In other words, even lower resistance and optical loss can be achieved. This makes it possible to provide a surface-emitting laser capable of improving the optical output without increasing the operating voltage, even in a structure in which the p type and the n type are reversed.

### 2-4. Fourth Embodiment

A surface-emitting laser according to a fourth embodiment of the present technique will be described next. The fourth embodiment may have basically the same configuration as the second embodiment, but the impurity concentration profile of the multilayer reflector is different from that in the second embodiment.

### 2-4-1. Configuration

The configuration of the surface-emitting laser according to the fourth embodiment may be basically the same as in the second embodiment described above. As described above, the configuration of the second embodiment may be basically the same as that of the first embodiment. Accordingly, the descriptions of the configuration of the first embodiment also apply to the fourth embodiment.

### 2-4-2. Average Impurity Concentrations in Multilayer Reflectors

In the fourth embodiment, the average impurity concentrations in the first multilayer reflector and/or the second multilayer reflector can be designed as follows.

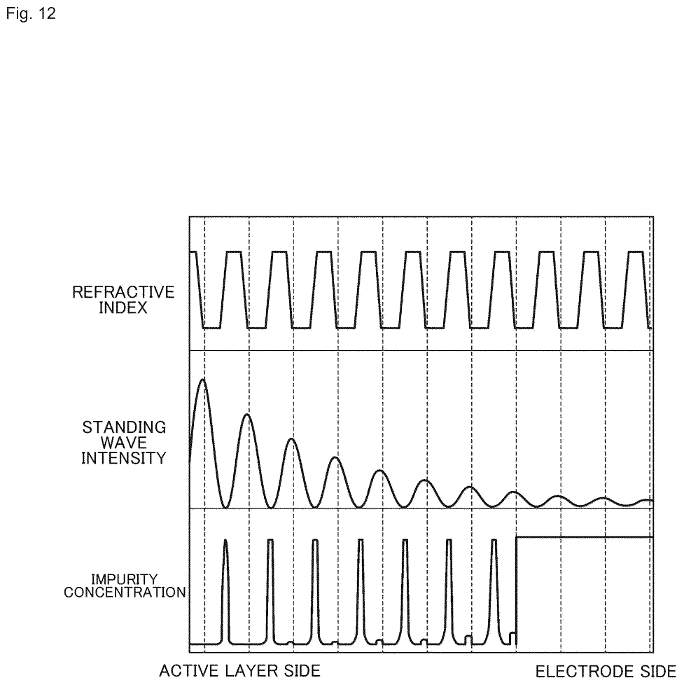

FIG. 12 is a schematic graph illustrating an example of a refractive index, a standing wave intensity, and an average impurity concentration in the multilayer reflector of the surface-emitting laser according to the fourth embodiment. In the graph, the horizontal axis represents the distance of the surface-emitting laser in a longitudinal direction, and the vertical axis represents the refractive index, the standing wave intensity, and the average impurity concentration.

The multilayer reflector has a layered structure in which X layered units are layered (here, X is a positive integer). The layered unit includes a low refractive index layer, a first graded layer, a high refractive index layer, and a second graded layer in that order from the active layer side. Accordingly, the multilayer reflector has X pairs each constituted by the low refractive index layer, the first graded layer, the high refractive index layer, and the second graded layer. As illustrated in FIG. 12, in the multilayer reflector of the fourth embodiment, the impurity concentration is designed based on the theory described in the second embodiment up to a Y-th pair (where Y is a positive integer satisfying Y<X) as counted from the active layer side, and the impurity concentration is constant after the Y+1-th pair.

In the fourth embodiment, up to the Y-th pair in the multilayer reflector, the impurity concentration is relatively higher in parts having a lower standing wave intensity, whereas the impurity concentration is relatively lower in parts having a higher standing wave intensity. This makes it possible to suppress the resistance and to minimize optical absorption loss up to the Y-th pair in the multilayer reflector. In other words, even lower resistance and optical loss can be achieved. This makes it possible to provide a surface-emitting laser capable of improving the optical output without increasing the operating voltage. On the other hand, when the multilayer reflector is viewed as a whole, the effects of reducing the resistance and the optical loss are considered to be limited compared to the second embodiment. However, in the fourth embodiment, the impurity concentrations are the same for the Y+1-th and subsequent pairs in the multilayer reflector, and thus the time required for the development of the surface-emitting laser can be reduced. The method for designing the impurity concentrations may therefore be determined in light of the costs involved in the development of the surface-emitting laser and the characteristics obtained.

In the surface-emitting laser according to the fourth embodiment, at least one of the first multilayer reflector or the second multilayer reflector may have the specific impurity concentration mentioned above. When one is a p-type semiconductor multilayer reflector and the other is an n-type semiconductor multilayer reflector, it is preferable that the p-type semiconductor multilayer reflector have the specific impurity concentration mentioned above. To achieve even lower resistance and optical loss in the surface-emitting laser as a whole, it is further preferable that both the first multilayer reflector and the second multilayer reflector have the specific impurity concentration mentioned above.

### 2-5. Fifth Embodiment

A surface-emitting laser according to a fifth embodiment of the present technique will be described next. The fifth embodiment differs from the first embodiment in terms of part of the configuration, and differs from the first to fourth embodiments in terms of the method for designing the average impurity concentrations.

### 2-5-1. Configuration

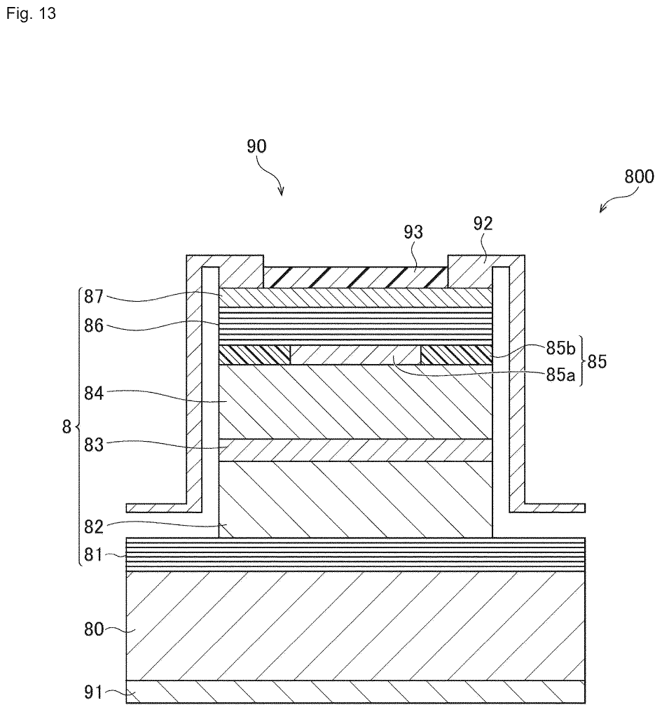

FIG. 13 is a schematic cross-sectional view illustrating the configuration of a surface-emitting laser 800 according to the fifth embodiment. In the surface-emitting laser 800 illustrated in FIG. 13, the upper side is the front side and the lower side is the rear side.

As illustrated in FIG. 13, the surface-emitting laser 800 includes a substrate 80 and a semiconductor layered body 8 on the substrate 80. The substrate 80 is, for example, an n-type GaAs substrate. The semiconductor layer 8 is, for example, a layered body formed from a GaAs-based semiconductor.

The semiconductor layered body 8 includes a first multilayer reflector 81, a first spacer layer 82, an active layer 83, a second spacer layer 84, a current confinement layer 85, a second multilayer reflector 86, and a contact layer 87 in that order from the substrate 80 side. The semiconductor layered body 8 has a cylindrical mesa part 90 protruding in the vertical direction from the substrate 80 in areas aside from part of the first multilayer reflector 81.

The surface-emitting laser 800 further includes a first electrode layer 91 and a second electrode layer 92. The first electrode layer 91 is formed in contact with the rear side of the substrate 80. The second electrode layer 82 is formed along the front surface of the mesa part 90.

In the fifth embodiment, for example, there are not only situations where the sum of the thicknesses of the first spacer layer 82, the active layer 83, and the second spacer layer 84 has a resonator length of 1λ, but there are also situations where, for example, at least one of the first spacer layer 82 or the second spacer layer 84 is thick, and the sum of the thicknesses of the first spacer layer 82, the active layer 83, and the second spacer layer 84 has a resonator length of at least 2λ.

In the fifth embodiment, the configurations other than those described above may be the same as in the first embodiment, and the descriptions of the configurations in the first embodiment also apply to the fifth embodiment.

### 2-5-2. Average Impurity Concentrations in Multilayer Reflectors and Other Layers

In the fifth embodiment, the average impurity concentrations in the first multilayer reflector 81, the second multilayer reflector 86, and other layers can be designed as follows.

A method for designing the average impurity concentrations of the first multilayer reflector 81 and the first spacer layer 82 will be described next. The first multilayer reflector 81 and the first spacer layer 82 are assumed to be layered structures in which unit layers having a thickness t [nm] are layered. In this case, in a K-th unit layer from the active layer side (where K is a positive integer), the standing wave intensity is represented by V_{K}, the free carrier absorption is represented by aₖ [1/cm], the resistance is represented by R_{K} [ohm], and the average impurity concentration is represented by C_{K} [cm⁻³]. A function related to a distance from a reference point is f(z). a, b, and c are constants. At this time, aₖ and R_{K} are the values represented by the following formulae (I) and (II), respectively.

$${α}_{K} = 1 - exp ( - a * {C}_{K} * {t}_{K} ) \qquad ( I )$$

$${R}_{K} = b * ( {C}_{K} \hat{} c ) * t * f ( z ) \qquad ( II )$$

In addition, the optical absorption loss in the first multilayer reflector 81 and the first spacer layer 82, and the resistance of the first multilayer reflector 81 and the first spacer layer 82, are represented by the following formulae, respectively.

$$Optical absorption loss = \sum {V}_{K} \cdot {α}_{K}$$

$$Resistance = \sum {R}_{K}$$

In this case, the values of the optical absorption loss and resistance are minimized using the average impurity concentration of each unit layer as a variable. For example, when the first multilayer reflector 81 and the first spacer layer 82 are 2000 nm thick in total and the unit layers are 2 nm thick, an optimization calculation is performed taking the average impurity concentration of a layered structure in which 1000 unit layers are layered as a variable, such that the optical absorption loss is minimized and the resistance is constant. The average impurity concentration of each unit layer is determined in this manner.

The method for designing the average impurity concentrations of the second spacer layer 84, the current confinement layer 85, and the second multilayer reflector 86 is also the same as the design method described above. The average impurity concentration of each unit layer is determined by performing an optimization calculation as described above by taking, as a variable, a value obtained by dividing the sum of the thicknesses of the second spacer layer 84, the current confinement layer 85, and second multilayer reflector 86 by the thickness of the unit layer.

The differences between the fifth embodiment and the first embodiment are as follows. In the first embodiment, the average impurity concentrations in the first multilayer reflector 31 and/or the second multilayer reflector 36 are determined through a specific design method. In contrast, in the fifth embodiment, the average impurity concentrations of layers other than the first multilayer reflector 81 and the second multilayer reflector 86 (specifically, the first spacer layer 82, the second spacer layer 84, and the current confinement layer 85) are also determined through a specific design method. Designing the average impurity concentrations for the surface-emitting laser as a whole more finely in such a manner makes it possible to achieve even lower resistance and optical loss than when only the average impurity concentration of the first multilayer reflector 31 and/or the second multilayer reflector 36 is designed more finely. As a result, the effect of increasing the optical output without increasing the operating voltage can be anticipated to be achieved even more than in the first embodiment.

### 2-6. Variations

The present technique is not limited to the foregoing embodiments, and many variations can be made thereon. For example, the methods for designing the average impurity concentrations in the first, second, or fourth embodiments can be used in combination with each other.

For example, the method for designing the average impurity concentration in the second embodiment can be used for the p-type multilayer reflector, and the method for designing the average impurity concentration in the first embodiment can be used for the n-type multilayer reflector.

For example, the methods for designing the average impurity concentrations in the first, second, or fourth embodiments can be used in combination with each other, even in a surface-emitting laser in which the p type and the n type are reversed as in the third embodiment.

The fourth embodiment described an example in which the method for designing the average impurity concentration of the second embodiment is used up to the Y-th pair of the X pairs in the multilayer reflector, and the average impurity concentration is constant for the Y+1-th and subsequent pairs. However, the configuration is not limited thereto, and the combination of the method for designing the average impurity concentration of the first or second embodiment, and the constant, may be freely changed.

Additionally, although the foregoing embodiments described an arsenide semiconductor laser as an example, the surface-emitting laser according to the present technique may be a Group III-V semiconductor including, for example, nitrogen (N), boron (B), antimony (Sb), or phosphorus (P).

The effects described in the present specification are merely illustrative and not limitative, and other effects may be obtained. The present technique may provide at least one effect among the multiple effects described in the present specification.

The present technique can also take on the following configurations.

[1]

A vertical-cavity surface-emitting laser including:
a first multilayer reflector, an active layer, and a second multilayer reflector, in that order,
wherein the first multilayer reflector and/or the second multilayer reflector has a layered structure in which N layered units are layered (where N is a positive integer),
the layered unit includes a low refractive index layer, a first graded layer, a high refractive index layer, and a second graded layer, in that order from a side on which the active layer is located,
the low refractive index layer has a refractive index that is lowest among the layers included in the layered unit,
the high refractive index layer has a refractive index that is highest among the layers included in the layered unit,
a refractive index of the first graded layer increases with distance from the low refractive index layer adjacent thereto in the layering direction,
a refractive index of the second graded layer decreases with distance from the high refractive index layer adjacent thereto in the layering direction, and
when average impurity concentrations of the low refractive index layer, the first graded layer, the high refractive index layer, and the second graded layer included in the layered unit that is M-th (where M is an integer satisfying 2≤M≤N) from the side on which the active layer is located are C_{M1}, C_{M2}, C_{M3}, and C_{M4}, respectively, and an average impurity concentration of the first graded layer included in the layered unit M−1-th from the side on which the active layer is located is C_{M2-1}, then C_{M2}≥C_{M1}, C_{M2}≥C_{M3}, C_{M2}≥C_{M4}, and C_{M2}≥C_{M2-1}.
   [2]

The vertical-cavity surface-emitting laser according to [1],
wherein when the average impurity concentration of the second graded layer included in the layered unit M−1-th from the side on which the active layer is located is C_{M4-1}, then C_{M4}≥C_{M4-1}.
   [3]

The vertical-cavity surface-emitting laser according to [1] or [2],
wherein when an average impurity concentration of the low refractive index layer included in the layered unit M−1-th from the side on which the active layer is located is C_{M1-1}, then C_{M1}≥C_{M1-1}.
   [4]

The vertical-cavity surface-emitting laser according to any one of [1] to [3], wherein when an average impurity concentration of the high refractive index layer included in the layered unit M−1-th from the side on which the active layer is located is C_{M3-1}, then C_{M3}≥C_{M3-1}.

[5]

The vertical-cavity surface-emitting laser according to any one of [1] to [4], wherein in the layered structure of the first multilayer reflector and/or the second multilayer reflector, an average impurity concentration increases exponentially with distance from the active layer in at least one of a plurality of the low refractive index layers, a plurality of the first graded layers, a plurality of the high refractive index layers, or a plurality of the second graded layers.

[6]

The vertical-cavity surface-emitting laser according to any one of [1] to [5], wherein C_{M2}≥C_{M4}≥C_{M1} and C_{M2}≥C_{M4}≥C_{M3}.

[7]

The vertical-cavity surface-emitting laser according to any one of [1] to [6],
wherein when the layered structure is a layered structure in which unit layers each having a thickness t [nm] are layered,
when, in the unit layer K-th (where K is a positive integer) from the side on which the active layer is located, a standing wave intensity is represented by V_{K}, a free carrier absorption is represented by ax [1/cm], a resistance is represented by R_{K} [ohm], and an average impurity concentration is represented by C_{K} [cm⁻³], a function for a distance from a reference point is f(z), and a, b, and c are constants, aₖ and R_{K} are values represented by the following formula (I) and formula (II), respectively:

$${α}_{K} = 1 - exp ( - a * {C}_{K} * {t}_{K} ) ; and \qquad ( I )$$

$${R}_{K} = b * ( {C}_{K} \hat{} c ) * t * f ( z ) , \qquad ( II )$$

when optical absorption loss in the layered structure is represented by ΣV_{K}·a_{K} and a resistance in the layered structure is represented by ΣR_{K}, and C_{K} is set such that ΣV_{K}·α_{K} is a minimum value and ΣR_{K} is a constant,
a profile of C_{K} and an inverse profile of V_{K} overlap at least partially.
   [8]

The vertical-cavity surface-emitting laser according to any one of [1] to [7],
wherein the first multilayer reflector or the second multilayer reflector is a p-type semiconductor multilayer reflector containing a p-type impurity, and
a concentration of the p-type impurity in the p-type semiconductor multilayer reflector is at least 7×10¹⁷ cm⁻³ and at most 8×10¹⁸ cm⁻³.
   [9]

The vertical-cavity surface-emitting laser according to [8],
wherein the p-type impurity includes C and/or Zn. [10]

The vertical-cavity surface-emitting laser according to any one of [1] to [9],
wherein the first multilayer reflector or the second multilayer reflector is an n-type semiconductor multilayer reflector containing an n-type impurity, and
a concentration of the n-type impurity in the n-type semiconductor multilayer reflector is at least 5×10¹⁷ cm⁻³ and at most 4×10¹⁸ cm⁻³.
   [11]

The vertical-cavity surface-emitting laser according to [10],
wherein the n-type impurity includes at least one element selected from Si, Se, and Te.

The vertical-cavity surface-emitting laser according to any one of [1] to [11],
wherein the first multilayer reflector and/or the second multilayer reflector is constituted by AlₓGa₁₋ₓAs (0≤x≤1).

The vertical-cavity surface-emitting laser according to claim 1,
wherein the low refractive index layer is an Alₓ₁Ga₁₋ₓ₁As layer (0<x1≤1),
the high refractive index layer is an Alₓ₂Ga₁₋ₓ₂As layer (0<x2≤x1),
the first graded layer is an Al_{y1}Ga_{1-y1}As layer (x2≤y1≤x1), and y1 decreases from x1 to x2 with distance from the low refractive index layer adjacent thereto in the layering direction, and
the second graded layer is an Al_{y2}Ga_{1-y2}As layer (x2≤y2≤x1), and y2 increases from x2 to x1 with distance from the high refractive index layer adjacent thereto in the layering direction.

### REFERENCE SIGNS LIST

3, 6, 8 Semiconductor layered body
30, 60, 80 Substrate
31, 63, 81 First multilayer reflector
32, 65, 82 First spacer layer
33, 66, 83 Active layer
34, 67, 84 Second spacer layer
35, 64, 85 Current confinement layer
35a, 64a, 85a Current injection region
35b, 64b, 85b Current confinement region
36, 68, 86 Second multilayer reflector
37, 87 Contact layer
40, 70, 90 Mesa part
41, 71, 91 First electrode layer
42, 72, 92 Second electrode layer
43, 73, 93 Insulating film
50 Oxidized layer
61 Current diffusion layer
62 First contact layer
69 Second contact layer
300, 600, 800 Surface-emitting laser

1. A vertical-cavity surface-emitting laser comprising:
a first multilayer reflector, an active layer, and a second multilayer reflector, in that order,
wherein the first multilayer reflector and/or the second multilayer reflector has a layered structure in which N layered units are layered (where N is a positive integer),
the layered unit includes a low refractive index layer, a first graded layer, a high refractive index layer, and a second graded layer, in that order from a side on which the active layer is located,
the low refractive index layer has a refractive index that is lowest among the layers included in the layered unit,
the high refractive index layer has a refractive index that is highest among the layers included in the layered unit,
a refractive index of the first graded layer increases with distance from the low refractive index layer adjacent thereto in the layering direction,
a refractive index of the second graded layer decreases with distance from the high refractive index layer adjacent thereto in the layering direction, and
when average impurity concentrations of the low refractive index layer, the first graded layer, the high refractive index layer, and the second graded layer included in the layered unit that is M-th (where M is an integer satisfying 2≤M≤N) from the side on which the active layer is located are C_{M1}, C_{M2}, C_{M3}, and C_{M4}, respectively, and an average impurity concentration of the first graded layer included in the layered unit M−1-th from the side on which the active layer is located is C_{M2-1}, then C_{M2}≥C_{M1}, C_{M2}≥C_{M3}, C_{M2}≥C_{M4}, and C_{M2}≥C_{M2-1}.

2. The vertical-cavity surface-emitting laser according to claim 1,
wherein when the average impurity concentration of the second graded layer included in the layered unit M−1-th from the side on which the active layer is located is C_{M4-1}, then C_{M4}≥C_{M4-1}.

3. The vertical-cavity surface-emitting laser according to claim 1,
wherein when an average impurity concentration of the low refractive index layer included in the layered unit M−1-th from the side on which the active layer is located is C_{M1-1}, then C_{M1}≥C_{M1-1}.

4. The vertical-cavity surface-emitting laser according to claim 1,
wherein when an average impurity concentration of the high refractive index layer included in the layered unit M−1-th from the side on which the active layer is located is C_{M3-1}, then C_{M3}≥C_{M3-1}.

5. The vertical-cavity surface-emitting laser according to claim 1,
wherein in the layered structure of the first multilayer reflector and/or the second multilayer reflector, an average impurity concentration increases exponentially with distance from the active layer in at least one of a plurality of the low refractive index layers, a plurality of the first graded layers, a plurality of the high refractive index layers, or a plurality of the second graded layers.

6. The vertical-cavity surface-emitting laser according to claim 1,
wherein C_{M2}≥C_{M4}≥C_{M1} and C_{M2}≥C_{M4}≥C_{M3}.

7. The vertical-cavity surface-emitting laser according to claim 1,
wherein when the layered structure is a layered structure in which unit layers each having a thickness t [nm] are layered,
when, in the unit layer K-th (where K is a positive integer) from the side on which the active layer is located, a standing wave intensity is represented by V_{K}, a free carrier absorption is represented by αK [1/cm], a resistance is represented by R_{K} [ohm], and an average impurity concentration is represented by C_{K} [cm⁻³], a function for a distance from a reference point is f(z), and a, b, and c are constants, α_{K} and R_{K} are values represented by the following formula (I) and formula (II), respectively:
$${α}_{K} = 1 - exp ( - a * {C}_{K} * {t}_{K} ) ; and \qquad ( I )$$
$${R}_{K} = b * ( {C}_{K} \hat{} c ) * t * f ( z ) , \qquad ( II )$$
when optical absorption loss in the layered structure is represented by ΣV_{K}·αK and a resistance in the layered structure is represented by ΣR_{K}, and C_{K} is set such that ΣV_{K}·α_{K} is a minimum value and ΣR_{K} is a constant,
a profile of C_{K} and an inverse profile of V_{K} overlap at least partially.

8. The vertical-cavity surface-emitting laser according to claim 1,
wherein the first multilayer reflector or the second multilayer reflector is a p-type semiconductor multilayer reflector containing a p-type impurity, and
a concentration of the p-type impurity in the p-type semiconductor multilayer reflector is at least 7×10¹⁷ cm⁻³ and at most 8×10¹⁸ cm⁻³.

9. The vertical-cavity surface-emitting laser according to claim 8,
wherein the p-type impurity includes C and/or Zn.

10. The vertical-cavity surface-emitting laser according to claim 1,
wherein the first multilayer reflector or the second multilayer reflector is an n-type semiconductor multilayer reflector containing an n-type impurity, and
a concentration of the n-type impurity in the n-type semiconductor multilayer reflector is at least 5×10¹⁷ cm⁻³ and at most 4×10¹⁸ cm⁻³.

11. The vertical-cavity surface-emitting laser according to claim 10,
wherein the n-type impurity includes at least one element selected from Si, Se, and Te.

12. The vertical-cavity surface-emitting laser according to claim 1,
wherein the first multilayer reflector and/or the second multilayer reflector is constituted by AlₓGa₁₋ₓAs (0≤x≤1).

13. The vertical-cavity surface-emitting laser according to claim 1,
wherein the low refractive index layer is an Alₓ₁Ga₁₋ₓ₁As layer (0<x1≤1),
the high refractive index layer is an Alₓ₂Ga₁₋ₓ₂As layer (0<x2≤x1),
the first graded layer is an Al_{y1}Ga_{1-y1}As layer (x2≤y1≤x1), and y1 decreases from x1 to x2 with distance from the low refractive index layer adjacent thereto in the layering direction, and
the second graded layer is an Al_{y2}Ga_{1-y2}As layer (x2≤y2≤x1), and y2 increases from x2 to x1 with distance from the high refractive index layer adjacent thereto in the layering direction.
